(19) United States
(12) Patent Application Publication
(10) Pub. No.: US 2011/0006830 A1
(43) Pub. Date: Jan. 13, 2011

(54) HIGH CURRENT CONTROL CIRCUIT INCLUDING METAL-INSULATOR TRANSITION DEVICE, AND SYSTEM INCLUDING THE HIGH CURRENT CONTROL CIRCUIT

(75) Inventors: Hyun-Tak Kim, Daejeon-city (KR); Bong-Jun Kim, Daejeon-city (KR); Sun-Jin Yun, Daejeon-city (KR)

Correspondence Address: RABIN & Berdo, PC, 1101 14TH STREET, NW, SUITE 500, WASHINGTON, DC, 20005, US

(73) Assignee: ELECTRONICS AND TELECOMMUNICATIONS RESEARCH INSTITUTE, Daejeon-city (KR)

(21) Appl. No.: 12/919,950

(22) PCT Filed: Feb. 27, 2009
(86) PCT No.: PCT/KR09/00932

§ 371 Date: Aug. 27, 2010

(30) Foreign Application Priority Data
Feb. 28, 2008 (KR) 10-2008-0018557
Sep. 17, 2008 (KR) 10-2008-0091266

(51) Int. Cl. H03K 17/60

(52) U.S. Cl. 327/478

(57) ABSTRACT

Provided are a high current control circuit including a metal-insulator transition (MIT) device, and a system including the high current control circuit so that a high current can be controlled and switched by the small-size high current control circuit, and a heat generation problem can be solved. The high current control circuit includes the MIT device connected to a current driving device and undergoing an abrupt MIT at a predetermined transition voltage; and a switching control transistor connected between the current driving device and the MIT device and controlling on-off switching of the MIT device. By including the metal-insulator transition (MIT) device, the high current control circuit switches a high current that is input to or output from the current driving device. Also, the MIT device constitutes a MIT-TR composite device with a heat-preventing transistor which prevents heat generation and is connected to the MIT device.

### CROSS-REFERENCE TO RELATED PATENT APPLICATION

This application claims the benefit of Korean Patent Application Nos. 10-2008-0018557, filed on Feb. 28, 2008, and 10-2008-0091266, filed on Sep. 17, 2008 in the Korean Intellectual Property Office, the disclosures of which are incorporated herein their entirety by reference.

### BACKGROUND OF THE INVENTION

1. Field of the Invention

The present invention relates to a metal-insulator transition (MIT) device, and more particularly, to a circuit including the MIT device, capable of controlling a high current with low temperature heat in that high-temperature heat is generated in a transistor when a high current flows through the transistor.

2. Description of the Related Art

Conventionally, in order to control and switch a high current, e.g., a current having a current density of about 10⁶ A/cm², power semiconductor transistors have been used. However, in general, semiconductors have a current density of about 10² to about 10⁴ A/cm², thus, it is difficult to switch a high current by using semiconductor transistors. Accordingly, a power semiconductor transistor employing semiconductor is used with their maximum areas to operate at a temperature higher than 100□, thereby generating high-temperature heat.

FIG. 1 is a diagram of a circuit for controlling a high current by using a conventional semiconductor transistor 10.

Referring to FIG. 1, the conventional semiconductor transistor 10 is serially connected to a current driving device 20 so as to control a high current of the current driving device 20, and a control pulse is applied to a base terminal of the conventional semiconductor transistor 10 so that the high current in the current driving device 20 is controlled. Here, a resistor R1 30 is connected to the current driving device 20 to adjust a current that is input to the current driving device 20, and a resistor R2 40 is connected to the base terminal of the conventional semiconductor transistor 10 to adjust a voltage of the control pulse voltage that is applied to the base terminal of the conventional semiconductor transistor 10.

In the case of the circuit for controlling the high current by using the conventional semiconductor transistor 10, high-temperature heat is generated in the conventional semiconductor transistor 10, as described above, and thus, a heat radiation plate for heat radiation is generally formed to solve this high-temperature heat problem.

Thus, the power semiconductor transistors incur high packaging costs due to the high-temperature heat problem, and have large sizes due to the inclusion of the heat radiation plate, etc. As a result, electric and electronic systems using such power semiconductor transistors are obliged to have large sizes due to the large sizes of the power semiconductor transistors, and also incur high costs. Accordingly, there is an increasing demand for the development of a device or a method of controlling and switching a high current, without using a semiconductor transistor and without being limited by the material properties with respect to an allowable current level.

### SUMMARY OF THE INVENTION

The present invention provides a high current control circuit including a metal-insulator transition (MIT) device, and a system including the high current control circuit so that a high current can be controlled and switched by the small-size high current control circuit, and thus, a heat generation problem caused in a conventional semiconductor transistor, as described above, can be solved.

According to an aspect of the present invention, there is provided a high current control circuit comprising an MIT device for switching a high current that is input to or output from a current driving device, the high current control circuit including the MIT device connected to the current driving device, and undergoing an abrupt MIT at a predetermined transition voltage; and a switching control transistor connected between the current driving device and the MIT device, and controlling on-off switching of the MIT device.

The MIT device may constitute a MIT-TR composite device with a heat-preventing transistor which prevents heat generation and is connected to the MIT device, and the heat-preventing transistor may be a bipolar transistor that is one of an NPN-type bipolar transistor and a PNP-type bipolar transistor, or may be a metal-oxide semiconductor (MOS) transistor that is one of a P-MOS transistor, an N-MOS transistor, and a C-MOS transistor.

When the heat-preventing transistor is the bipolar transistor, a first electrode of the MIT device, a second electrode of the MIT device, an emitter electrode of the bipolar transistor may be respectively connected to a collector electrode of the bipolar transistor, a base electrode of the bipolar transistor, and ground, and the first electrode of the MIT device and the collector electrode of the bipolar transistor may be connected to the current driving device and the switching control transistor, and the second electrode of the MIT device and the base electrode of the bipolar transistor may be connected to ground via a MIT resistor for protection of the MIT device.

When the heat-preventing transistor is the MOS transistor, a first electrode of the MIT device, a second electrode of the MIT device, and a source electrode of the MOS transistor may be respectively connected to a drain electrode of the MOS transistor, a gate electrode of the MOS transistor, and ground, and the first electrode of the MIT device and the drain electrode of the MOS transistor may be connected to the current driving device and the switching control transistor, and the second electrode of the MIT device and the gate electrode of the MOS transistor may be connected to ground via a MIT resistor for protection of the MIT device.

The switching control transistor may be a bipolar transistor that is one of an NPN-type bipolar transistor and a PNP-type bipolar transistor, or may be a MOS transistor that is one of a P-MOS transistor, an N-MOS transistor, and a C-MOS transistor. For example, when the switching control transistor is the NPN-type bipolar transistor, the NPN-type bipolar transistor may be connected with a common collector structure between the current driving device and the MIT-TR composite device, or NPN-type bipolar transistor may be connected with a common emitter structure between the current driving device and the MIT-TR composite device.

A resistor having a predetermined resistance value may be connected between the base electrode of the NPN-type bipolar transistor and the pulse power source.

The MIT device may include a MIT thin film that undergoes the abrupt MIT according to variation of physical properties including temperature, pressure, voltage, and an electromagnetic wave. For example, the MIT thin film may be formed of vanadium dioxide (VO₂). Meanwhile, the MIT-TR composite device and the switching control transistor may be integrated and packaged as a small-size chip.

According to another aspect of the present invention, there is provided a high current control circuit system that is formed of a plurality of unit circuits which are integrally arrayed or disposed in an array structure, wherein the unit circuits each correspond to a high current control circuit that comprises a MIT device, a heat-preventing transistor connected to the MIT device, and a switching control transistor connected between the MIT device and the heat preventing transistor.

According to another aspect of the present invention, there is provided an electric and electronic system that includes the high current control circuit.

The MIT device may constitute a MIT-TR composite device with a heat-preventing transistor which prevents heat generation and is connected to the MIT device, and the electric and electronic system may include a current driving system; a secondary cell supplying power to the current driving system; a first MIT device serially connected between the current driving system and the secondary cell, and undergoing an abrupt MIT at a transition voltage; and the MIT-TR composite device connected in parallel with the secondary cell.

The secondary cell may be a lithium ion cell, the MIT device may undergo the abrupt MIT at a predetermined critical temperature or higher, and when a temperature of the lithium ion cell exceeds the predetermined critical temperature, the MIT-TR composite device may discharge charges of the lithium ion cell to prevent explosion of the lithium ion cell.

The MIT device may constitute a MIT-TR composite device with a heat-preventing transistor which prevents heat generation and is connected to the MIT device, and the electric and electronic system may include a current driving system; a secondary cell supplying a power to the current driving system; a Positive Temperature Coefficient (PTC) device serially connected between the current driving system and the secondary cell, and blocking an over-current to the current driving system; and the MIT-TR composite device connected in parallel with the secondary cell.

The MIT device may undergo an abrupt MIT at a critical temperature or higher, the PTC device may block a current at the critical temperature, and when a temperature of the secondary cell exceeds the critical temperature, the PTC device may block a current supply to the current driving system, and the MIT-TR composite device may discharge charges of the secondary cell, whereby explosion of the secondary cell may be prevented.

The electric and electronic system may correspond to a system including mobile phones, notebook computers, switching power supplies, and motor controlling controllers which demand current control.

### BRIEF DESCRIPTION OF THE DRAWINGS

The above and other features and advantages of the present invention will become more apparent by describing in detail exemplary embodiments thereof with reference to the attached drawings in which:

FIG. 1 is a diagram of a circuit for controlling a high current by using a conventional semiconductor transistor;

FIGS. 2A and 2B respectively correspond to a cross-sectional view and a plane view of a metal-insulator transition (MIT) device having a horizontal structure;

FIG. 3A is a graph showing an abrupt MIT generated by applying a voltage to a MIT device that is formed of vanadium dioxide (VO₂);

FIG. 3B is a graph of resistance versus temperature of a MIT device formed of VO₂;

FIGS. 4A and 4B are equivalent circuit diagrams of MIT-TR composite devices comprising MIT devices and transistors, respectively;

FIG. 5 is a circuit diagram of a high current control circuit including the MIT-TR composite device of FIG. 4A and a switching control transistor, according to an embodiment of the present invention;

FIG. 6 is a circuit diagram of a high current control circuit including the MIT-TR composite device and a switching control transistor, according to another embodiment of the present invention;

FIG. 7 is a cross-sectional view of a high current controlling integrated device in which the MIT-TR composite device and the switching control transistor in the high current control circuit of FIG. 5 are integrated as one chip;

FIGS. 8A and 8B are graphs showing test data obtained by inputting pulses having 1 kHz and 300 kHz frequencies to a base electrode of the switching control transistor of FIG. 5;

FIG. 9 is a diagram of a circuit that uses the MIT-TR composite device so as to prevent explosion of a lithium ion cell, according to another embodiment of the present invention; and

FIG. 10 is a diagram of a circuit in which a MIT device M2 for blocking current of FIG. 9 is replaced by a Positive Temperature Coefficient (PTC) device.

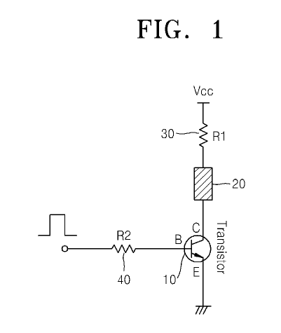

### DETAILED DESCRIPTION OF THE INVENTION

The present invention will now be described more fully with reference to the accompanying drawings, in which exemplary embodiments of the invention are shown. Throughout the specification, it will be understood that when an element is referred to as being “on” another element, it can be directly on the other element, or intervening elements may also be present. In the drawings, the thicknesses of layers and regions are exaggerated for clarity. Like reference numerals in the drawings denote like elements, and thus their description will be omitted. Meanwhile, it will be understood by those of ordinary skill in the art that terms in the present invention are used therein without departing from the spirit and scope of the present invention as defined by the following claims. In the following description, well-known functions or constructions are not described in detail since they would obscure the invention with unnecessary detail.

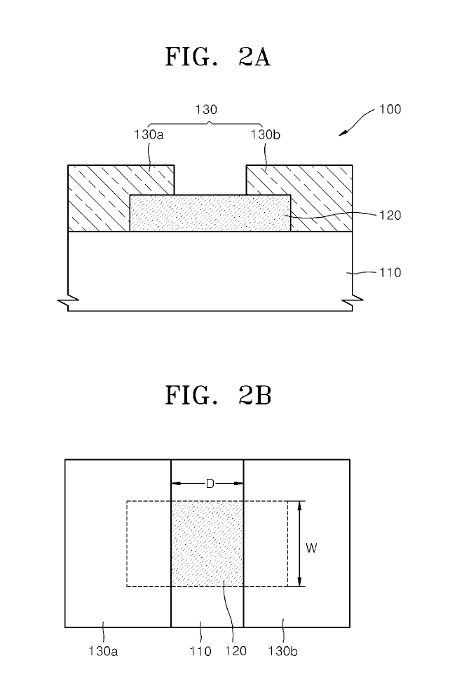

FIGS. 2A and 2B respectively correspond to a cross-sectional view and a plane view of a metal-insulator transition (MIT) device 100 having a horizontal structure.

Referring to FIG. 2A, the MIT device 100 having the horizontal structure includes a substrate 110, a MIT thin film 120 formed on the substrate 110, and an electrode thin film including first and second electrode thin films 130a and 130b which are formed on the substrate 110 and part of the MIT thin film 120 so as to face each other at side and top surfaces of the MIT thin film 120. That is, the first electrode thin film 130a and the second electrode thin film 130b are separated from one another by the MIT thin film 120.

Meanwhile, a buffer layer may be further formed on the substrate 110 so as to decrease a lattice mismatch between the MIT thin film 120 and the substrate 110. The electrical characteristics of the MIT thin film 120 change according to variation of physical properties such as temperature, pressure, voltage, and electromagnetic wave, etc. For example, an electrical characteristic of the MIT thin film 120 sharply changes at a predetermined transition voltage or higher, or at a predetermined critical temperature or higher when a constant predetermined voltage is applied to the MIT thin film 120. That is, the MIT thin film 120 remain as an insulator at a transition voltage or lower, or at a critical temperature or lower but, when the MIT thin film 120 generates an abrupt MIT at a transition voltage or higher, or at a critical temperature or higher, and changes to a metal.

A material and a method for forming the MIT thin film 120, the electrode thin film 130, and the substrate 110 have already been disclosed in Korean laid-open patents related to a MIT device, and thus, a description thereof will be omitted here. Meanwhile, the MIT thin film 120 may be formed to be a thin film type such as, a ceramic thin film or a single crystal thin film having a very small size, and thus, the MIT device 100 may be manufactured as a very small device having a micro meter (μm) size and may require low manufacturing costs.

The MIT device 100 has a horizontal structure. However, the present invention is not limited thereto and thus the MIT device 100 may also have a vertical structure by sequentially forming a first electrode thin film, a MIT thin film, and a second electrode thin film on a substrate.

FIG. 2B is a plane view of the MIT device 100 of FIG. 2A. In FIG. 2B, the elements forming the MIT device 100, that is, the substrate 100, the MIT thin film 120, and the first and second electrode thin films 130a and 130b, are illustrated. As described above, the MIT device 100 undergoes the abrupt MIT at a transition voltage or higher, or at a critical temperature or higher. Such a transition voltage or a critical temperature may vary according to the materials of the elements forming the MIT device 100 or may vary according to a structure of the MIT device 100. For example, by varying a distance D between the first electrode thin film 130a and the second electrode thin film 130b, or by varying a width W of the MIT thin film 120, the transition voltage or the critical temperature of the MIT device 100 may vary.

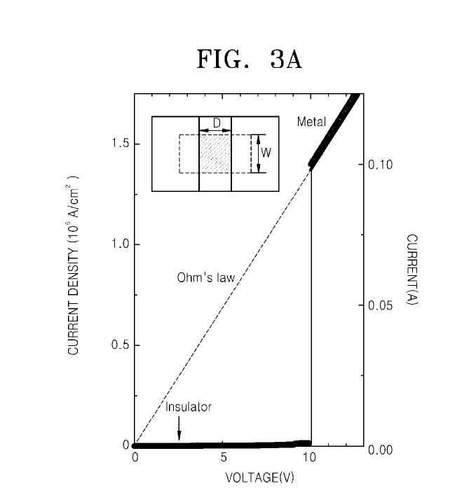

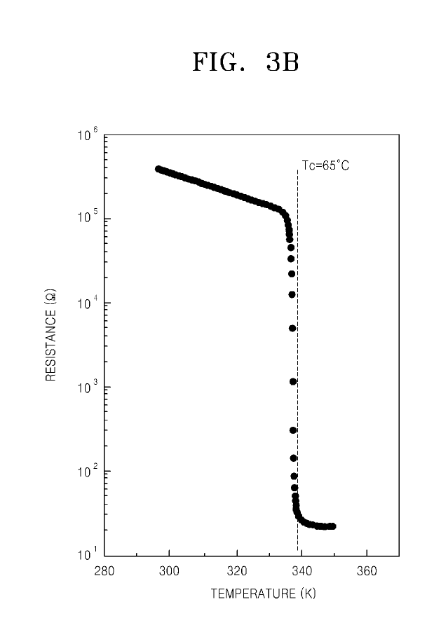

FIG. 3A is a graph showing an abrupt MIT generated by applying a voltage to a MIT device that is formed of vanadium dioxide (VO₂), where a horizontal axis indicates the voltage applied to the MIT device and a vertical axis indicates current density (left-vertical axis of the graph) and a current (right-vertical axis of the graph) which flow in the MIT device.

Referring to FIG. 3A, it is apparent that the MIT device has insulator characteristics until the voltage increases to around 10V at which the MIT device undergoes an abrupt current jump, thereby having metal characteristics. Thus, it is understood that the measured transition voltage of the MIT device is approximately 10V. After the MIT device undergoes an abrupt MIT, the MIT device having metal characteristics follows the Ohm's law. Here, a dotted line is the Ohm's law line, that extends a current-voltage line that follows the Ohm's law to the point before the MIT device undergoes an abrupt MIT, as shown in the graph of FIG. 3A.

FIG. 3B is a graph of resistance versus temperature of a MIT device formed of VO₂, where a horizontal axis indicates an absolute temperature in Kelvins, and a vertical axis indicates the resistance in Ohms (Ω). Also, a constant predetermined voltage is applied to the MIT device.

Referring to FIG. 3B, the MIT device has a resistance greater than 10⁵Ω at a temperature less than 340 K, thereby having insulator characteristics. However, the MIT device undergoes an abrupt discontinuous transition at 340K or a temperature higher than 340 K, thereby having metal characteristics and a resistance of several tens Ω. Referring to FIG. 3B, the MIT device undergoes an abrupt MIT at the 340 K temperature, and thus, it is understood that a critical temperature of the MIT device is approximately 340 K.

Although not illustrated in the drawings, the MIT device may undergo an abrupt MIT from other physical properties such as pressure, an electric field, and an electromagnetic wave, as well as due to the voltage and the temperature, which are applied to the MIT device. However, such other physical properties may obscure the concept of the present invention, and thus, detailed descriptions thereof will be omitted here.

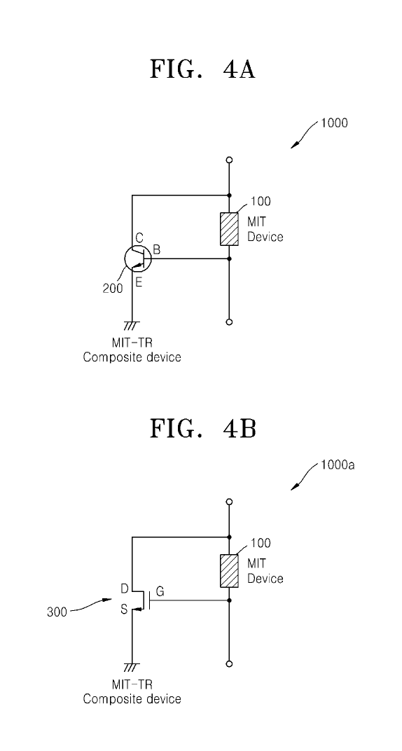

FIGS. 4A and 4B are equivalent circuit diagrams of MIT-TR composite devices 1000 and 1000a comprising MIT devices 100 and heat-preventing transistors 200 and 300, respectively.

Referring to FIG. 4A, the MIT-TR composite device 1000 includes the MIT device 100 undergoing an abrupt MIT at a transition voltage, and the heat-preventing transistor 200 connected to the MIT device 100. Here, the MIT device 100 is connected between a collector electrode and a base electrode of the heat-preventing transistor 200. Meanwhile, an emitter electrode of the heat-preventing transistor 200 is connected to ground.

The MIT-TR composite device 1000 having such a structure is connected to a current driving device (not shown) so that the MIT device 100 controls a current of the current driving device, and the heat-preventing transistor 200 prevents a self-heating of the MIT device 100. Meanwhile, in the case where the MIT-TR composite device 1000 is used for current control, a MIT resistor (not shown) is connected to a node where the base electrode of the heat-preventing transistor 200 and the MIT device 100 are commonly connected.

Functions of the MIT-TR composite device 1000 will now be described in detail. When a voltage higher than a transition voltage is applied to the MIT device 100, the MIT device 100 undergoes an abrupt MIT so that a high current flows via the MIT device 100. Even if a voltage less than the transition voltage is applied to the MIT device 100 while the high current flows, the electrical characteristics of the MIT device 100 do not return to those of an insulator, and the high current continuously flows such that a switching error of the MIT device 100 may occur due to the self-heating of the MIT device 100. That is, when the high current flows via the MIT device 100, the MIT device 100 self-heats, thereby causing hysteresis. Since the hysteresis prevents switching of the MIT device 100, it is necessary to remove the hysteresis.

In order to prevent the self-heating of the MIT device 100, that is, in order to prevent the hysteresis, the heat-preventing transistor 200 is connected to the MIT device 100. To be more specific, before the MIT device 100 undergoes the abrupt MIT, the heat-preventing transistor 200 is in a turn-off state due to a small voltage difference between the emitter electrode and the base electrode. In other words, since a high voltage is primarily applied to the MIT device 100, only a low voltage is applied to the MIT resistor such that the voltage difference between the emitter electrode and the base electrode cannot exceed a critical voltage. However, when the MIT device 100 undergoes the abrupt MIT, the electrical characteristics of the MIT device 100 change to metal characteristics so that the high current flows via the MIT device 100, the low voltage is applied to the MIT device 100, and the high voltage is applied to the MIT resistor. That is, the high voltage is applied to the base electrode. Thus, the heat-preventing transistor 200 turns on, and a current flows through the heat-preventing transistor 200. Accordingly, a current flowing through the MIT device 100 decreases. Also, due to the current decrease, the electrical characteristics of the MIT device 100 return to insulator characteristics, and thus, the heat-preventing transistor 200 returns to the turn-off state.

In this manner, by including the MIT device 100 that undergoes the abrupt MIT at the transition voltage and the heat-preventing transistor 200 that prevents the self-heating of the MIT device 100, the MIT-TR composite device 1000 may prevent the self-heating of the MIT device 100 and may efficiently control the current driving device via switching of the MIT device 100.

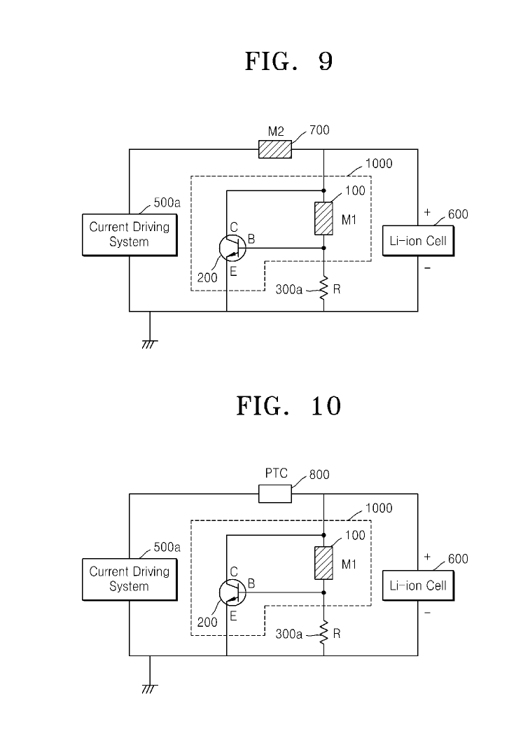

In the above, the MIT-TR composite device 1000 is described based on the transition voltage of the MIT device 100. However, the MIT-TR composite device 1000 may also perform the same functions based on a critical temperature, and in that case, the MIT-TR composite device 1000 may function as a protection circuit for the current driving device, as will be described later with reference to FIGS. 9A and 9B.

In the present embodiment, an NPN-type bipolar transistor is used as the heat-preventing transistor 200; however the present invention is not limited thereto and thus a PNP-type bipolar transistor may be used as the heat-preventing transistor 200 of the MIT-TR composite device 1000.

Referring to FIG. 4B, the MIT-TR composite device 1000a is similar to the MIT-TR composite device 1000 of FIG. 4A but the MIT-TR composite device 1000a differs in that a metal-oxide semiconductor (MOS) transistor is used as a heat-preventing transistor 300 instead of a bipolar transistor. Meanwhile, any one of a P-MOS transistor, an N-MOS transistor or a C-MOS transistor may be used as the MOS transistor.

When the base electrode, the collector electrode, and the emitter electrode of the heat-preventing transistor 200 of FIG. 4A are respectively replaced by a gate electrode, a drain electrode, and a source electrode of the heat-preventing transistor 300, the connections between the devices are the same as those of the heat-preventing transistor 200 of FIG. 4A. That is, the MIT device 100 is connected between the drain electrode and the gate electrode of the heat-preventing transistor 300, and the source electrode of the heat-preventing transistor 300 is connected to ground. Meanwhile, when the MIT-TR composite device 1000a is connected to a current driving device (not shown), the drain electrode and one electrode of the MIT device 100 are connected to the current driving device, and the gate electrode and the other electrode of the MIT device 100 are connected to a MIT resistor (not shown).

Functions of the MIT-TR composite device 1000a based on the aforementioned connections are the same as those of the MIT-TR composite device 1000 of FIG. 4A.

FIG. 5 is a circuit diagram of a high current control circuit including the MIT-TR composite device 1000 and a switching control transistor 400, according to an embodiment of the present invention.

Referring to FIG. 5, the high current control circuit according to the current embodiment includes the MIT-TR composite device 1000 of FIG. 4, and the switching control transistor 400 that controls on-off switching of the MIT-TR composite device 1000. In the present embodiment, the high current control circuit includes the MIT-TR composite device 1000; however, the present invention is not limited thereto and thus the high current control circuit can also include the MIT-TR composite device 1000a of FIG. 4B.

One terminal of the MIT-TR composite device 1000 is connected to a current driving device 500 and the switching control transistor 400, and the other terminal of the MIT-TR composite device 1000 is connected to ground via a MIT resistor device R2 300. Here, the current driving device 500 may be a relay, a light-emitting diode, a buzzer, etc. Meanwhile, a resistor R1 510 for adjusting current is serially connected between the current driving device 500 and a power source that supplies a power voltage Vcc.

The switching control transistor 400 according to the current embodiment may be one of an NPN-type bipolar transistor and a PNP-type bipolar transistor, or may be one of a P-MOS transistor, an N-MOS transistor or a C-MOS transistor.

In the present embodiment, an NPN-type bipolar transistor is used as the switching control transistor 400. The switching control transistor 400 has a common collector structure in which the MIT-TR composite device 1000 and the current driving device 500 are commonly connected to the collector electrode of the switching control transistor 400. That is, an emitter electrode of the switching control transistor 400 having such a common collector structure is connected to ground, and a base electrode of the switching control transistor 400 is connected to a pulse power source for controlling switching. Meanwhile, a transistor resistor R3 440 is connected between the base electrode of the switching control transistor 400 and the pulse power source.

Operations of the high current control circuit connected as described above will now be described.

In the high current control circuit according to the current embodiment, when a voltage applied to the MIT device 100 in the MIT-TR composite device 1000 is higher than a transition voltage that generates an abrupt MIT, the MIT device 100 undergoes the abrupt MIT so that a high current I_{CC} (>I_{MIT}) flows. By allowing a collector current I_{C} of the switching control transistor 400 to be flowed or to be blocked, the high current control circuit controls the high current of the current driving device 500. Here, I_{MIT} indicates a critical current required for the MIT device 100 to undergo the abrupt MIT. Thus, when the collector current I_{C}=0 amps, that is, when the collector current I_{C} equals 0 amps, since the switching control transistor 400 is at an off-state, I_{CC}>I_{MIT} occurs so that the MIT device 100 undergoes the abrupt MIT, and the high current flows through the MIT device 100. When the collector current I_{C} equals to a predetermined value, that is, when the collector current l_{c} flows through the switching control transistor 400, since the switching control transistor 400 changes to an on-state, I_{CC}−I_{C}<I_{MIT} occurs so that the MIT device 100 does not undergo the abrupt MIT, and a flow of the high current toward the MIT device 100 is blocked. Accordingly, the flow of the high current of the current driving device 500 is blocked.

Eventually, an on-off control on the MIT device 100, that is, generation and non-generation of the abrupt MIT are controlled by an on-off control of the switching control transistor 400. This on-off control of the switching control transistor 400 is performed with a pulse voltage input to the base electrode of the switching control transistor 400. In other words, the switching control transistor 400 turns on when a high voltage is input to its base electrode, and the switching control transistor 400 turns off when a low voltage is input to its base electrode.

Meanwhile, the MIT-TR composite device 1000 according to the current embodiment includes the heat-preventing transistor 200 so as to prevent a self-heating of the MIT device 100. Thus, the MIT device 100 may smoothly perform a switching operation without generating heat. For example, a conventional semiconductor transistor is used as a switching device at 20 through 150 kHz since the conventional semiconductor transistor has a heat generation problem. However, the MIT device 100 included in the MIT-TR composite device 1000 according to the current embodiment may perform a switching operation even at 1 MHz or higher, thereby being enabled to be efficiently used as a commercial switch. In the case where the MIT device 100 generates low temperature heat, the MIT device 100 may be solely used without the heat-preventing transistor 200, instead of the MIT-TR composite device 1000.

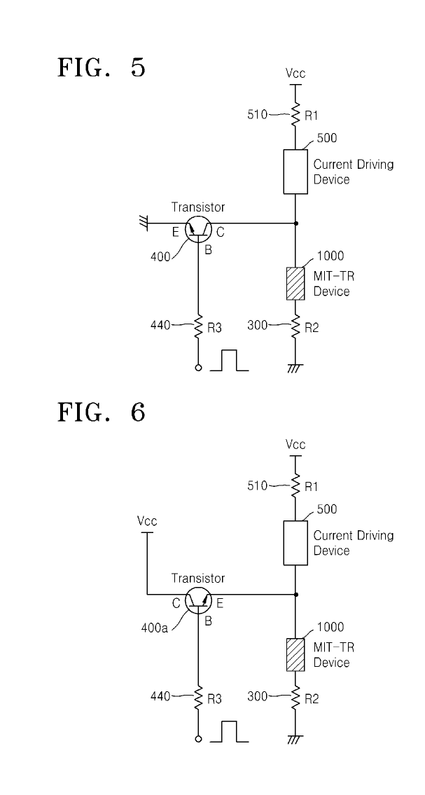

FIG. 6 is a circuit diagram of a high current control circuit including the MIT-TR composite device 1000 and a switching control transistor 400a, according to another embodiment of the present invention.

Referring to FIG. 6, the high current control circuit of the current embodiment is similar to the high current control circuit of the embodiment of FIG. 5 but the high current control circuit of the current embodiment differs in that the high current control circuit of the current embodiment uses an NPN-type bipolar transistor having a common emitter structure, as the switching control transistor 400a. Accordingly, an emitter electrode of the switching control transistor 400a having the common emitter structure is commonly connected to a current driving device 500 and the MIT-TR composite device 1000, a power source supplying a predetermined voltage Vcc is connected to a collector electrode of the switching control transistor 400a, and a pulse power source for controlling switching is connected a base electrode of the switching control transistor 400a. Meanwhile, the transistor resistor R3 440 is connected between the base electrode of the switching control transistor 400a and the pulse power source.

Operations of the high current control circuit connected as described above will now be described.

In the high current control circuit of the current embodiment, when a low current I_{CC} that does not generate an abrupt MIT in the MIT device 100 included in the MIT-TR composite device 1000 flows through the MIT device 100, that is, when the low current I_{CC} being less than a critical current (I_{CC}<I_{MIT}) flows through the MIT device 100. By allowing a predetermined emitter current I_{E} to flow to the emitter electrode of the switching control transistor 400a, the high current control circuit allows the MIT device 100 to undergo the abrupt MIT. In other words, when the emitter current I_{E}=0 amps, that is, when the emitter current I_{E} equals 0 amps since the switching control transistor 400a is at an off-state, I_{MIT}>I_{CC} occurs so that the MIT device 100 does not undergo the abrupt MIT, and a flow of a high current toward the MIT device 100 is blocked. When the emitter current I_{E} equals to a predetermined value, that is, when the emitter current I_{E} flows through the emitter electrode since the switching control transistor 400a changes to an on-state, I_{MIT}≦Icc+I_{E} occurs so that the MIT device 100 undergoes the abrupt MIT, and the high current flows through the MIT device 100.

Eventually, the high current control circuit of the current embodiment operates in the inverse manner as the high current control circuit of the embodiment of FIG. 5. That is, when the switching control transistor 400a turns on, the high current flows through the MIT device 100, and when the switching control transistor 400a turns off, the flow of the high current toward the MIT device 100 is blocked. Accordingly, the flow of the high current of the current driving device 500 is controlled.

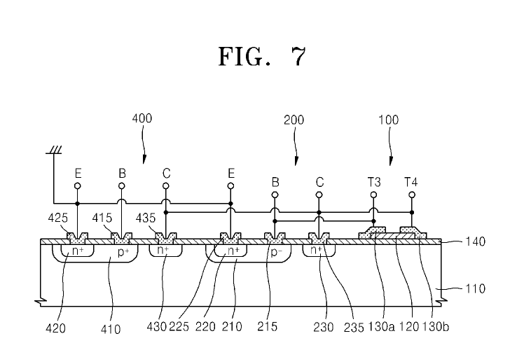

FIG. 7 is a cross-sectional view of a high current controlling integrated device in which the MIT-TR composite device 1000 and the switching control transistor 400 in the high current control circuit of FIG. 5 are integrated as one chip.

Referring to FIG. 7, the high current control circuit of FIG. 5 may have a structure in which the MIT-TR composite device 1000 and the switching control transistor 400 are integrated on a substrate 110 as one chip. Hereinafter, the high current controlling integrated device is referred to as ‘an integrated device for a high current control circuit’.

The integrated device for a high current control circuit includes the MIT device 100, the heat-preventing transistor 200, and the switching control transistor 400 which are formed together on the substrate 110. The MIT device 100 includes an insulating film 140, a MIT thin film 120, and two MIT electrodes 130a and 130b formed both contacting the MIT thin film 120 and the insulating film 140.

The heat-preventing transistor 200 includes a base electrode 215, an emitter electrode 225, and a collector electrode 235 which respectively contact active regions such as a base region 210, an emitter region 220, and a collector region 230 which are formed in the substrate 110. The insulating film 140 is formed on the substrate 110, and the base, emitter, and collector electrodes 215, 225, and 235 respectively contact the base, emitter, and collector regions 210, 220, and 230 by penetrating the insulating film 140.

Similar to the heat-preventing transistor 200, the switching control transistor 400 includes a base electrode 415, an emitter electrode 425, and a collector electrode 435 which respectively contact corresponding active regions 410, 420, and 430.

Meanwhile, the integrated device for a high current control circuit has a structure in which electrodes are connected therein. That is, the MIT electrode 130b of the MIT device 100 is connected to the collector electrodes 235 and 435 of the heat-preventing transistor 200 and the switching control transistor 400, and the MIT electrode 130a of the MIT device 100 is connected to the base electrode 215 of the heat-preventing transistor 200. Also, the emitter electrodes 225 and 425 of the heat-preventing transistor 200 and the switching control transistor 400 are connected to ground. When the integrated device for a high current control circuit is used for current control, the current driving device 500 is connected to the MIT electrode 130b of the MIT device 100, and a pulse power source is connected to the base electrode 415 of the switching control transistor 400.

Referring to FIG. 7, the heat-preventing transistor 200 and the switching control transistor 400 are disposed in a row direction. However, in consideration of forming the active regions, and electrode connections, each of the active regions of the heat-preventing transistor 200 and the switching control transistor 400 may be formed to be parallel to each other in a column direction (that is, in a downward direction toward a paper surface. However, positions of the MIT device 100, the heat-preventing transistor 200, and the switching control transistor 400 are not limited thereto and may vary. Meanwhile, the MIT resistor 300, or the transistor resistor 440 of the switching control transistor 400, each being connected to the MIT-TR composite device 1000, may also be formed on the substrate 110.

As illustrated in FIG. 7, the integrated device for a high current control circuit of FIG. 7 may be manufactured and packaged to have the structure in which devices are integrated, and thus, may be easily connected to a current driving device so as to control a high current of the current driving device. The integrated device for a high current control circuit of FIG. 7 may effectively prevent heat generation, may control a high current, and may not need a heat radiation plate so that the integrated device for a high current control circuit of FIG. 7 may be easily implemented as a small-size chip.

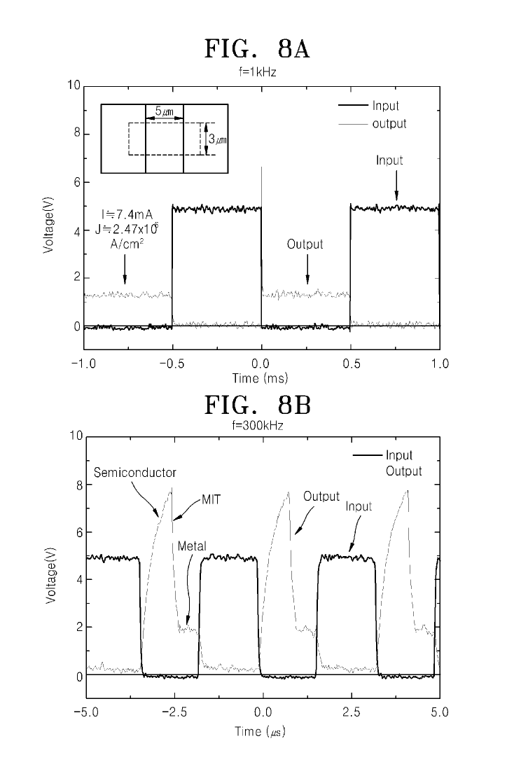

FIGS. 8A and 8B are graphs showing test data obtained by inputting pulses having 1 kHz and 300 kHz frequencies to the base electrode of the switching control transistor 400 of FIG. 5. Here, a MIT device used for the test has dimensions in which a thickness of a VO₂ thin film is 100 nm, a distance between electrodes is 5 μm, and a width of the VO₂ thin film is 3 μm. A layout of the MIT device is shown at an upper left corner of the graph in FIG. 8A. Also, the graph of FIG. 8A corresponds to a case in which the frequency of the pulse input to the switching control transistor 400 is 1 kHz, and the graph of FIG. 8B corresponds to a case in which the frequency of the pulse input to the switching control transistor 400 is 300 kHz.

Referring to FIGS. 8A and 8B, a current at which the MIT device undergoes an abrupt MIT is 7.4 mA, and current density J approximately equals 2.47×10⁶ A/cm² (that is, J≈2.47×10⁶ A/cm²). Meanwhile, the resistor R1=300Ω, the MIT resistor R2=1 kΩ, and the transistor resistor R3=10Ω (see FIG. 5) are used. A bold solid line in the graphs of FIGS. 8A and 8B indicates an input voltage to the base electrode of the switching control transistor 400, and a thin solid line indicates an output current from the electrodes of the MIT device.

A MIT device including a VO₂ thin film malfunctions or is unable to perform a switching operation when a temperature of the MIT device exceeds 70° C. However, referring to FIGS. 8A and 8B, it is apparent that a switching operation is successfully performed, which means that a temperature of the MIT device remains below 70° C. In other words, it can be understood that a self-heating of the MIT device is prevented by the heat-preventing transistor 200 so that the MIT device successfully performs the switching operation and simultaneously maintains its temperature below 70° C.

Eventually, the high current control circuit of FIG. 5 may use the MIT device having a structure much simpler than that of a conventional semiconductor transistor, thereby successfully switching a high current (current density J 2.47×10⁶ A/cm²) with low temperature heat. Meanwhile, the high current control circuit using the MIT device according to the embodiments of the present invention may perform a high current switching operation even at 1 MHz or higher, compared to a conventional switching device that is used at 20 kHz through 150 kHz. Thus, a MIT switch according to the embodiments of the present invention may perform a switching operation with respect to a high frequency of 1 MHz or higher so that the MIT switch may be usefully employed as a commercial switch.

Such a high current control circuit according to the embodiments of the present invention may be usefully applied to various electric and electronic systems including notebook computers, switching power supplies, and motor controlling controllers which demand current control.

FIG. 9 is a diagram of a circuit that uses the MIT-TR composite device 1000 so as to prevent explosion of a lithium ion cell 600, according to another embodiment of the present invention.

Referring to FIG. 9, the circuit according to the current embodiment includes the MIT-TR composite device 1000, the lithium ion cell 600, a current driving system 500a, and a MIT device M2 700 for blocking current. The circuit is different from the embodiment of FIG. 5 in that a power source and the current driving device 500 are respectively replaced by the lithium ion cell 600 and the current driving system 500a, and the MIT device M2 700 for blocking current is serially connected between the lithium ion cell 600 and the current driving system 500a. Here, a resistor R 300a corresponds to the MIT resistor R2 300 of FIG. 5. In the current embodiment, the circuit includes the lithium ion cell 600; however the present invention is not limited thereto, and thus, other cells can be used.

Here, the MIT device M2 700 for blocking current has a transition voltage of 4V or lower. Thus, when a voltage higher than the transition voltage of 4V is applied to the MIT device M2 700 for blocking current, the MIT device M2 700 for blocking current undergoes an abrupt MIT and has metal characteristics, thereby functioning as a conductive wire via which a high current may flow.

Meanwhile, an MIT device M1 100 included in the MIT-TR composite device 1000 undergoes an abrupt MIT at a predetermined critical temperature. Thus, except that the MIT device M1 100 undergoes the abrupt MIT at the critical temperature, not at a transition voltage, the MIT-TR composite device 1000 performs functions similar to the MIT-TR composite device 1000 of FIG. 4A. For example, when an ambient temperature, that is, a temperature of the lithium ion cell 600 or a conductive wire, rises above a critical temperature, the MIT device M1 100 included in the MIT-TR composite device 1000 of FIG. 9 undergoes the abrupt MIT so that the MIT-TR composite device 1000 bypasses a current so as to protect the lithium ion cell 600, and the MIT device 200 in the MIT-TR composite device 1000 prevents a self-heating of the MIT device M1 100.

Functions of the circuit having the configuration described above will now be described. When the lithium ion cell 600 is fully charged, it has a voltage of 4V. Here, the MIT device M2 700 for blocking current, which is serially connected between the fully charged lithium ion cell 600 and the current driving system 500a, undergoes an abrupt MIT, operates as a metal and thus can be used as a conductive wire. Meanwhile, when an ambient temperature or a conductive wire temperature exceeds a critical temperature (e.g., 70° C.) of the MIT device M1 100 due to certain external changes, the MIT device M1 100 included in the MIT-TR composite device 1000 operates to suddenly discharge charges in the lithium ion cell 600, thereby preventing explosion of the lithium ion cell 600. With this sudden discharge of charges, a voltage of the lithium ion cell 600 is dropped so that the MIT device M2 700 for blocking current returns to operates as an insulator so as to block a current supply to the current driving system 500a.

FIG. 10 is a diagram of a circuit in which the MIT device M2 700 for blocking current of FIG. 9 is replaced by a Positive Temperature Coefficient (PTC) device 800.

Referring to FIG. 10, the circuit uses the PTC device 800, instead of using the MIT device M2 700 for blocking current of FIG. 9, and functions of the PTC device 800 are similar to those of the MIT device M2 700 for blocking current. That is, when an ambient temperature or a conductive wire temperature exceeds a critical temperature (e.g., 70° C.) of the MIT device M1 100 due to certain external changes, the MIT device M1 100 included in the MIT-TR composite device 1000 operates to suddenly discharge charges in the lithium ion cell 600, thereby preventing explosion of the lithium ion cell 600. Meanwhile, when the ambient temperature rises, the resistance of the PTC device 800 increases so that a current supply to the current driving system 500a is blocked.

A high current control circuit including an MIT device and a system including the high current control circuit according to embodiments of the present invention may effectively prevent heat generation, and may simultaneously control high current. Also, a heat radiation plate is not necessary and thus it is possible to implement a small-size high current control circuit.

Thus, instead of a conventional high current control circuit using a power semiconductor transistor, the high current control circuit including the MIT device according to the embodiments of the present invention may efficiently perform a high current control. Accordingly, the high current control circuit including the MIT device according to the embodiments of the present invention may be usefully applied to various electric and electronic systems including notebook computers, switching power supplies, and motor controlling controllers which demand current control.

While this invention has been particularly shown and described with reference to exemplary embodiments thereof, it will be understood by those of ordinary skill in the art that various changes in form and details may be made therein without departing from the spirit and scope of the invention as defined by the appended claims. The exemplary embodiments should be considered in a descriptive sense only and not for purposes of limitation. Therefore, the scope of the invention is defined not by the detailed description of the invention but by the appended claims, and all differences within the scope will be construed as being included in the present invention.

What is claimed is:

1. A high current control circuit comprising an MIT (metal-insulator transition) device for switching a high current that is input to or output from a current driving device, the high current control circuit comprising:
the MIT device connected to the current driving device, and undergoing an abrupt MIT at a predetermined transition voltage; and
a switching control transistor connected between the current driving device and the MIT device, and controlling on-off switching of the MIT device.

2. The high current control circuit of claim 1, wherein the MIT device constitutes a MIT-TR composite device with a heat-preventing transistor which prevents heat generation and is connected to the MIT device, and the heat-preventing transistor is a bipolar transistor that is one of an NPN-type bipolar transistor and a PNP-type bipolar transistor, or is a MOS (metal-oxide semiconductor) transistor that is one of a P-MOS transistor, an N-MOS transistor, and a C-MOS transistor.

3. The high current control circuit of claim 2, wherein the heat-preventing transistor is the bipolar transistor,
a first electrode of the MIT device, a second electrode of the MIT device, an emitter electrode of the bipolar transistor are respectively connected to a collector electrode of the bipolar transistor, a base electrode of the bipolar transistor, and ground, and
the first electrode of the MIT device and the collector electrode of the bipolar transistor are connected to the current driving device and the switching control transistor, and the second electrode of the MIT device and the base electrode of the bipolar transistor are connected to ground via a MIT resistor for protection of the MIT device.

4. The high current control circuit of claim 2, wherein the heat-preventing transistor is the MOS transistor,
a first electrode of the MIT device, a second electrode of the MIT device, and a source electrode of the MOS transistor are respectively connected to a drain electrode of the MOS transistor, a gate electrode of the MOS transistor, and ground, and
the first electrode of the MIT device and the drain electrode of the MOS transistor are connected to the current driving device and the switching control transistor, and the second electrode of the MIT device and the gate electrode of the MOS transistor are connected to ground via a MIT resistor for protection of the MIT device.

5. The high current control circuit of claim 2, wherein the switching control transistor is a bipolar transistor that is one of an NPN-type bipolar transistor and a PNP-type bipolar transistor, or is a MOS transistor that is one of a P-MOS transistor, an N-MOS transistor, and a C-MOS transistor.

6. The high current control circuit of claim 5, wherein the switching control transistor is the NPN-type bipolar transistor, and
the NPN-type bipolar transistor is connected with a common collector structure between the current driving device and the MIT-TR composite device, or NPN-type bipolar transistor is connected with a common emitter structure between the current driving device and the MIT-TR composite device.

7. The high current control circuit of claim 6, wherein, when the NPN-type bipolar transistor is connected with the common collector structure, an emitter electrode of the NPN-type bipolar transistor is connected to ground, and a pulse power source for controlling the switching is connected a base electrode of the NPN-type bipolar transistor.

8. The high current control circuit of claim 6, wherein, when the NPN-type bipolar transistor is connected with the common emitter structure, a collector electrode of the NPN-type bipolar transistor is connected to a voltage source having a predetermined voltage, and a pulse power source for controlling the switching is connected the base electrode of the NPN-type bipolar transistor.

9. The high current control circuit of claim 7, wherein a resistor having a predetermined resistance value is connected between the base electrode of the NPN-type bipolar transistor and the pulse power source.

10. The high current control circuit of claim 2, wherein the heat-preventing transistor is the bipolar transistor,
a first electrode of the MIT device, a second electrode of the MIT device, an emitter electrode of the bipolar transistor are respectively connected to a collector electrode of the bipolar transistor, a base electrode of the bipolar transistor, and ground, and
the first electrode of the MIT device and the collector electrode of the bipolar transistor are connected to the current driving device and the switching control transistor, and the second electrode of the MIT device and the base electrode of the bipolar transistor are connected to ground via a MIT resistor for protection of the MIT device; and
wherein the switching control transistor is the NPN-type bipolar transistor, and
the NPN-type bipolar transistor is connected with a common collector structure between the current driving device and the MIT-TR composite device, or the NPN-type bipolar transistor is connected with a common emitter structure between the current driving device and the MIT-TR composite device.

11. The high current control circuit of claim 2, wherein the heat-preventing transistor is the MOS transistor,
a first electrode of the MIT device, a second electrode of the MIT device, and a source electrode of the MOS transistor are respectively connected to a drain electrode of the MOS transistor, a gate electrode of the MOS transistor, and ground, and
the first electrode of the MIT device and the drain electrode of the MOS transistor are connected to the current driving device and the switching control transistor, and the second electrode of the MIT device and the gate electrode of the MOS transistor are connected to ground via a MIT resistor for protection of the MIT device; and
wherein the switching control transistor is the NPN-type bipolar transistor, and
the NPN-type bipolar transistor is connected with a common collector structure between the current driving device and the MIT-TR composite device, or the NPN-type bipolar transistor is connected with a common emitter structure between the current driving device and the MIT-TR composite device.

12. The high current control circuit of claim 1, wherein the MIT device comprises a MIT thin film that undergoes the abrupt MIT according to variation of physical properties including temperature, pressure, voltage, and an electromagnetic wave.

13. The high current control circuit of claim 12, wherein the MIT thin film is formed of vanadium dioxide (VO₂).

14. The high current control circuit of claim 2, wherein the MIT-TR composite device and the switching control transistor are integrated and packaged as a small-size chip.

15. A high current control circuit system that is formed of a plurality of unit circuits which are integrally arrayed or disposed in an array structure, wherein the unit circuits each correspond to a high current control circuit that comprises a MIT device, a heat-preventing transistor connected to the MIT device, and a switching control transistor connected between the MIT device and the heat preventing transistor.

16. An electric and electronic system that comprises the high current control circuit of claim 1.

17. The electric and electronic system of claim 16, wherein the MIT device constitutes a MIT-TR composite device with a heat-preventing transistor which prevents heat generation and is connected to the MIT device; and
the electric and electronic system comprises:
a current driving system;
a secondary cell supplying power to the current driving system;
a first MIT device serially connected between the current driving system and the secondary cell, and undergoing an abrupt MIT at a transition voltage; and
the MIT-TR composite device connected in parallel with the secondary cell.

18. The electric and electronic system of claim 17, wherein the secondary cell is a lithium ion cell, the MIT device undergoes the abrupt MIT at a predetermined critical temperature or higher, and when a temperature of the lithium ion cell exceeds the predetermined critical temperature, the MIT-TR composite device discharges charges of the lithium ion cell to prevent explosion of the lithium ion cell.

19. The electric and electronic system of claim 18, wherein the MIT-TR composite device comprises a MIT resistor protecting the MIT device, and
the heat-preventing transistor is a bipolar transistor that is one of an NPN-type bipolar transistor and a PNP-type bipolar transistor, or is a MOS transistor that is one of a P-MOS transistor, an N-MOS transistor, and a C-MOS transistor.

20. The electric and electronic system of claim 19, wherein the heat-preventing transistor is the bipolar transistor,
a first electrode of the MIT device, a second electrode of the MIT device, an emitter electrode of the bipolar transistor are respectively connected to a collector electrode of the bipolar transistor, a base electrode of the bipolar transistor, and ground, and
the first electrode of the MIT device and the collector electrode of the bipolar transistor are connected to the secondary cell and the first MIT device, and the second electrode of the MIT device and the base electrode of the bipolar transistor are connected to ground via the MIT resistor.

21. The electric and electronic system of claim 16, wherein the MIT device constitutes a MIT-TR composite device with a heat-preventing transistor which prevents heat generation and is connected to the MIT device; and
the electric and electronic system comprises:
a current driving system;
a secondary cell supplying a power to the current driving system;
a PTC (Positive Temperature Coefficient) device serially connected between the current driving system and the secondary cell, and blocking an over-current to the current driving system; and
the MIT-TR composite device connected in parallel with the secondary cell.

22. The electric and electronic system of claim 21, wherein the MIT device undergoes an abrupt MIT at a critical temperature or higher, the PTC device blocks a current at the critical temperature, and when a temperature of the secondary cell exceeds the critical temperature, the PTC device blocks a current supply to the current driving system and the MIT-TR composite device discharges charges of the secondary cell, whereby explosion of the secondary cell is prevented.

23. The electric and electronic system of claim 16, wherein the electric and electronic system corresponds to a system comprising mobile phones, notebook computers, switching power supplies, and motor controlling controllers which demand current control.
